(19) United States
(12) Patent Application Publication
(10) Pub. No.: US 2004/0240180 A1
(43) Pub. Date: Dec. 2, 2004

(54) Apparatus employing heat sink

(75) Inventors: Martin Joseph Crippen, Apex, NC (US); Jason Aaron Matteson, Raleigh, NC (US)

Correspondence Address: IBM CORPORATION, PO BOX 12195, DEPT 9CCA, BLDG 002, RESEARCH TRIANGLE PARK, NC, 27709, US

(73) Assignee: International Business Machines Corporation, Armonk, NY

(21) Appl. No.: 10/881,290

(22) Filed: Jun. 30, 2004

Related U.S. Application Data
(63) Continuation-in-part of application No. 10/300,058, filed on Nov. 20, 2002, now Pat. No. 6,807,058.

(51) Int. Cl. H05K 7/20

(52) U.S. Cl. 361/700

(57) ABSTRACT

The capability of an assembly to transfer heat from a semiconductor package source is enhanced while a reduction in the space required for effective operation is achieved. Bodies of fins defining tubular channels are affixed to oppositely facing surfaces of a rectilinear body which is adapted to receive heat from a semiconductor package.

### CROSS REFERENCE TO RELATED APPLICATIONS

This is a continuation-in-part of application Ser. No. 10/300,058, filed Nov. 20, 2002.

### FIELD AND BACKGROUND OF INVENTION

This invention relates to heat sinks for semiconductor packages and combinations of such a heat sink with devices from which heat must be transferred.

The generation of heat within semiconductor packages for devices such as microprocessors has long been recognized as requiring heat transfer arrangements to permit satisfactory operation of computer circuits and the like. As the technology has progressed, heat loads imposed have risen which space allowances have compressed. Thus problems arise in effectuating the necessary transfers of heat from increasingly confined spaces. Recently, heat loads from microprocessor have risen to exceed seventy five watts, while space allowances have shrunk to limit the available height for a heat sink to less than forty millimeters.

### SUMMARY OF THE INVENTION

With the above problems in mind, it is a purpose of the present invention to enhance the capability of an assembly to transfer heat from a semiconductor package source while enabling reduction in the space required for effective operation. In realizing this purpose of the present invention, bodies of fins are affixed to oppositely facing surfaces of a rectilinear body which is adapted to receive heat from a semiconductor package. In a preferred form of the invention, one body of fins is on the surface which is adapted to engage the semiconductor package.

### BRIEF DESCRIPTION OF THE DRAWINGS

Some of the purposes of the invention having been stated, others will appear as the description proceeds, when taken in connection with the accompanying drawings, in which:

FIG. 1 is a schematic perspective view of a heat sink in accordance with this invention showing a body of fins affixed to a first broad surface of a heat transferring body;

FIG. 2 is a view similar to FIG. 1 of the other side of the heat sink of FIG. 1;

FIG. 3 is a schematic perspective view of the heat sink of FIGS. 1 and 2 as assembled with a printed circuit board and a semiconductor package;

FIG. 4 is a schematic sectional view through the assembly of FIG. 3;

FIG. 5 is a front, top and right side exploded perspective view of a server blade system of the present invention.

FIG. 6 is a rear, top and left side perspective view of the rear portion of the server blade system. FIG. 7 is a schematic diagram of the server blade system's management subsystem.

FIG. 8 is a topographical illustration of the server blade system's management functions.

FIG. 9 is a block diagram of the switch module and processor blade interconnection.

### DETAILED DESCRIPTION OF INVENTION

While the present invention will be described more fully hereinafter with reference to the accompanying drawings, in which a preferred embodiment of the present invention is shown, it is to be understood at the outset of the description which follows that persons of skill in the appropriate arts may modify the invention here described while still achieving the favorable results of the invention. Accordingly, the description which follows is to be understood as being a broad, teaching disclosure directed to persons of skill in the appropriate arts, and not as limiting upon the present invention.

Referring now more particularly to the accompanying drawings, a heat sink in accordance with the present invention is there generally indicated at 10. The heat sink has a rectilinear body 11 of heat transferring material having opposing first and second broad surfaces, a first body of fins 12 affixed to the first broad surface and defining a first array of a plurality of elongate tubular channels directing heat transfer fluid flow, and a second body 14 of fins affixed to the opposite broad surface and defining a second array of a plurality of elongate tubular channels directing heat transfer fluid flow. In one form the body 11 essentially is a plate or moderately thick sheet of metal such as copper, silver or the like having a relatively high thermal conductivity. Such material, as is known, is effective to transfer heat efficiently from a high temperature source, such as a microprocessor, to a lower temperature sink, such as a flowing stream of cooling air. In an alternate form contemplated by this invention, the rectilinear body 11 may be a thin capsule heat pipe, formed by a relatively thin walled envelope within which is sealed a medium which transfers heat by phase change across a liquid/gas transition point. The technology of heat pipes is well known and need not be here discussed in detail. In either instance, the body 11 has length and width dimensions significantly greater than the thickness dimension.

The fin bodies 12 and 14 are affixed to opposite faces of the body 11 for purposes which will become more clear hereinafter. In each instance, the fins are closed one to another at the ends remote from affixation to the body 11, so that an adjacent pair of fins in the body define a tubular channel through which a cooling air flow is directed by appropriate air handling devices. The fact that the channels are closed, thus defining tubes, is significant in assuring that heat transfer rates desired for the heat sink of this invention are attained.

As shown more particularly in FIG. 2, the fin body 14 on one surface of the rectilinear body 11 covers less of the area of that surface. This allows provision of an area indicated at 15 for engagement with a semiconductor package, such as a packaged microprocessor, from which heat is to be drawn by the heat sink of this invention.

While it is only exemplary of this invention, it is noted that in the form shown one fin body 12 covers substantially the entire area of the surface to which it is affixed, while the other fin body 14 covers less than the entire area in order to allow for the contact area 15.

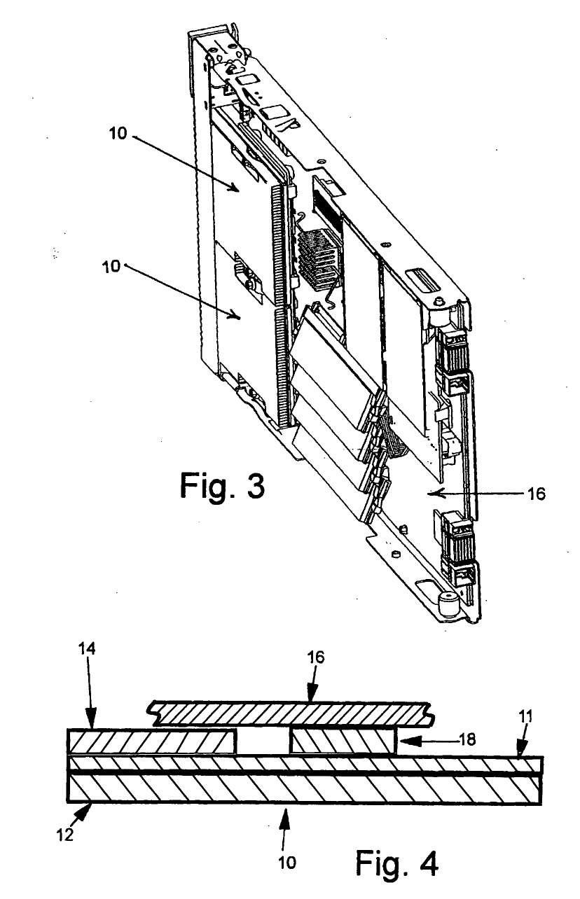

FIG. 3 illustrates a practical embodiment of a product in which two heat sinks in accordance with this invention are employed. The product includes a printed circuit board 16 on which are mounted semiconductor packages, two of which (not visible in FIG. 3) are cooled by use of heat sinks 10 in accordance with this invention.

FIG. 4 is a schematic illustration of a section through the circuit board 16, showing the engagement of the heat sink 10 with a semiconductor package 18. As will be noted there, the presence of the fin body 14 enables enhanced use of a surface of the rectilinear body 11 which otherwise would have significantly lower heat transfer capability by guiding air flowing immediately adjacent the printed circuit board through the elongate tubes provided by the fin body. Additionally, fin body 14, in forcing air to travel through its elongated tubes, provides resistance to air flow on its side of rectilinear body 11. This resistance provides a more balanced flow on both sides of rectilinear body 11 by forcing flow through fin body 12.

### Server Blade System Overview

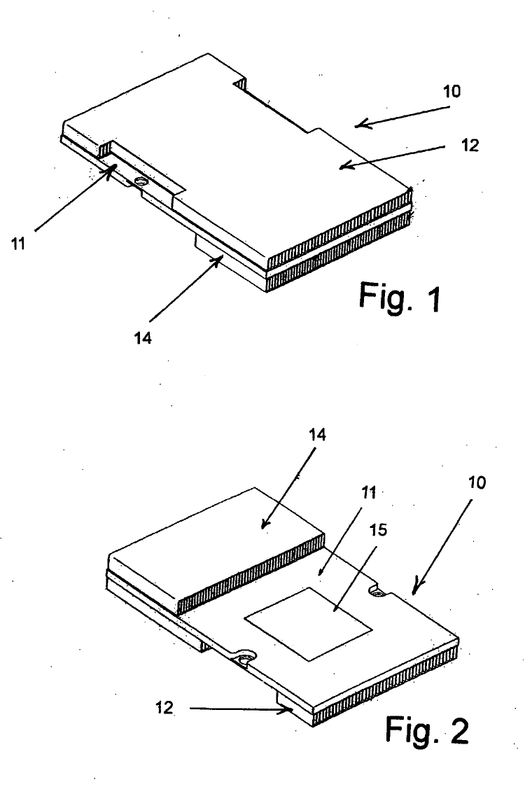

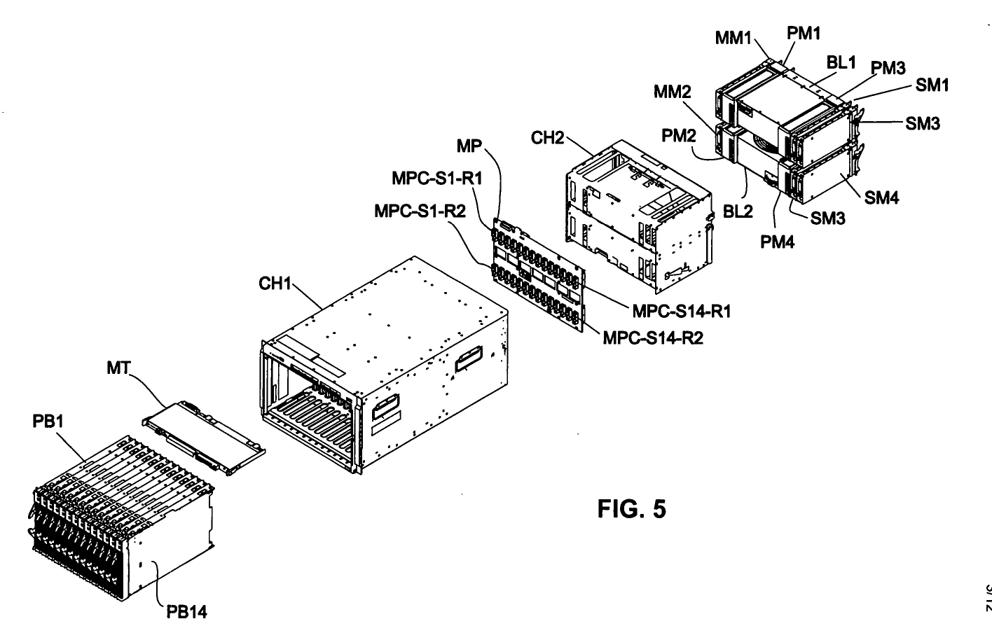

FIG. 5 is a front, top and right side exploded perspective view of a server blade system. Referring to this figure, main chassis CH1 houses all the components of the server blade system. Up to 14 processor blades PB1 through PB14 (or other blades, such as storage blades) are hot pluggable into the 14 slots in the front of chassis CH1. The assemblage shown in FIG. 3 is an example of a single processor blade having two processors, each processor having the inventive heat sink described above with reference to FIGS. 1-4. The term “server blade”, “processor blade”, or simply “blade” is used throughout the specification and claims, but it should be understood that these terms are not limited to blades that only perform “processor” or “server” functions, but also include blades that perform other functions, such as storage blades, which typically include hard disk drives and whose primary function is data storage.

Processor blades provide the processor, memory, hard disk storage and firmware of an industry standard server. In addition, they include keyboard, video and mouse (“KVM”) selection via a control panel, an onboard service processor, and access to the floppy and CD-ROM drives in the media tray. A daughter card is connected via an onboard PCI-X interface and is used to provide additional high-speed links to switch modules SM3 and SM4 (described below). Each processor blade also has a front panel with 5 LED's to indicate current status, plus four push-button switches for power on/off, selection of processor blade, reset, and NMI for core dumps for local control.

Blades may be ‘hot swapped’ without affecting the operation of other blades in the system. A server blade is typically implemented as a single slot card (394.2 mm×226.99 mm); however, in some cases a single processor blade may require two slots. A processor blade can use any microprocessor technology as long as it compliant with the mechanical and electrical interfaces, and the power and cooling requirements of the server blade system.

For redundancy, processor blades have two signal and power connectors; one connected to the upper connector of the corresponding slot of midplane MP (described below), and the other connected to the corresponding lower connector of the midplane. Processor Blades interface with other components in the server blade system via the following midplane interfaces: 1) Gigabit Ethernet (2 per blade; required); 2) Fibre Channel (2 per blade; optional); 3) management module serial link; 4) VGA analog video link; 4) keyboard/mouse USB link; 5) CD-ROM and floppy disk drive (“FDD”) USB link; 6) 12 VDC power; and 7) miscellaneous control signals. These interfaces provide the ability to communicate to other components in the server blade system such as management modules, switch modules, the CD-ROM and the FDD. These interfaces are duplicated on the midplane to provide redundancy. A processor blade typically supports booting from the media tray CDROM or FDD, the network (Fibre channel or Ethernet), or its local hard disk drive.

A media tray MT includes a floppy disk drive and a CD-ROM drive that can be coupled to any one of the 14 blades. The media tray also houses an interface board on which is mounted interface LED's, a thermistor for measuring inlet air temperature, and a 4-port USB controller hub. System level interface controls consist of power, location, over temperature, information, and general fault LED's and a USB port.

Midplane circuit board MP is positioned approximately in the middle of chassis CH1 and includes two rows of connectors; the top row including connectors MPC-S1-R1 through MPC-S14-R1, and the bottom row including connectors MPC-S1-R2 through MPC-S14-R2. Thus, each one of the 14 slots includes one pair of midplane connectors located one above the other (e.g., connectors MPC-S1-R1 and MPC-S1-R2) and each pair of midplane connectors mates to a pair of connectors at the rear edge of each processor blade (not visible in FIG. 5).

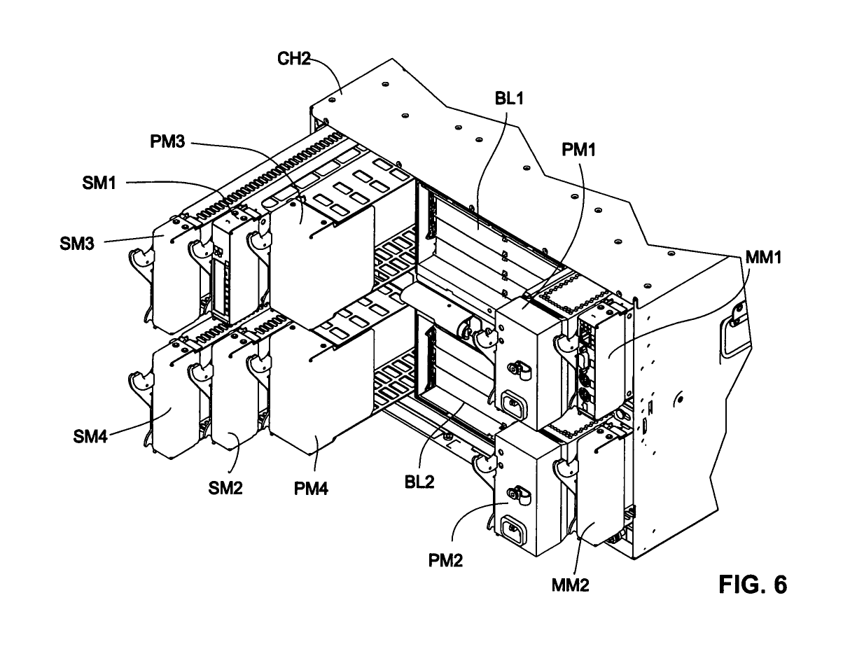

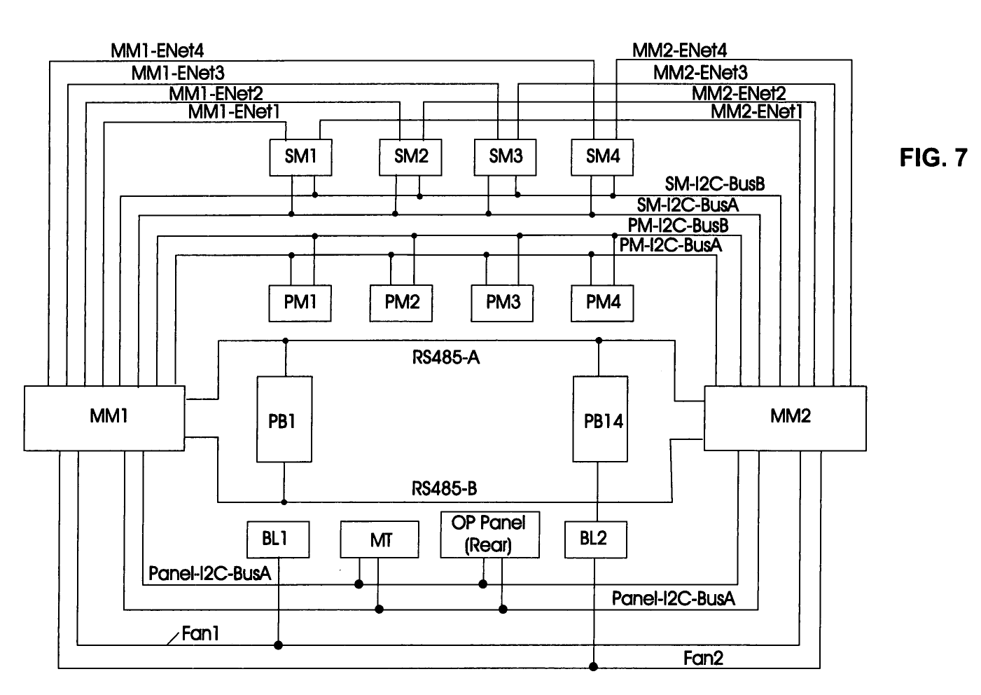

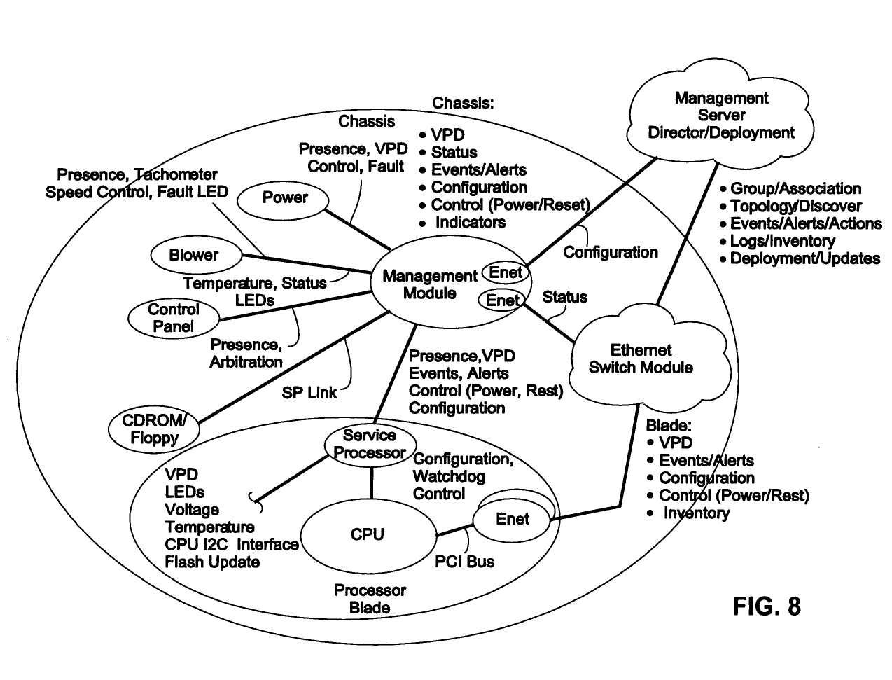

FIG. 6 is a rear, top and left side perspective view of the rear portion of the server blade system. Referring to FIGS. 5 and 6, a chassis CH2 houses various hot pluggable components for cooling, power, control and switching. Chassis CH2 slides and latches into the rear of main chassis CH1.

Two hot pluggable blowers BL1 and BL2 include backward-curved impeller blowers and provide redundant cooling to the server blade system components. Airflow is from the front to the rear of chassis CH1. Each of the processor blades PB1 through PB14 includes a front grille to admit air, and low-profile vapor chamber based heat sinks are used to cool the processors within the blades. Total airflow through the system chassis is about 300 CFM at 0.7 inches H2O static pressure drop. In the event of blower failure or removal, the speed of the remaining blower automatically increases to maintain the required air flow until the replacement unit is installed. Blower speed control is also controlled via a thermistor that constantly monitors inlet air temperature. The temperature of the server blade system components are also monitored and blower speed will increase automatically in response to rising temperature levels as reported by the various temperature sensors.

Four hot pluggable power modules PM1 through PM4 provide DC operating voltages for the processor blades and other components. One pair of power modules provides power to all the management modules and switch modules, plus any blades that are plugged into slots 1-6. The other pair of power modules provides power to any blades in slots 7-14. Within each pair of power modules, one power module acts as a backup for the other in the event the first power module fails or is removed. Thus, a minimum of two active power modules are required to power a fully featured and configured chassis loaded with 14 processor blades, 4 switch modules, 2 blowers, and 2 management modules. However, four power modules are needed to provide full redundancy and backup capability. The power modules are designed for operation between an AC input voltage range of 200 VAC to 240 VAC at 50/60 Hz and use an IEC320 C14 male appliance coupler. The power modules provide +12 VDC output to the midplane from which all server blade system components get their power. Two +12 VDC midplane power buses are used for redundancy and active current sharing of the output load between redundant power modules is performed.

Management modules MM1 through MM4 are hot-pluggable components that provide basic management functions such as controlling, monitoring, alerting, restarting and diagnostics. Management modules also provide other functions required to manage shared resources, such as the ability to switch the common keyboard, video, and mouse signals among processor blades.

FIG. 7 is a schematic diagram of the server blade system's management subsystem. Referring to this figure, each management module has a separate Ethernet link to each one of the switch modules SM1 through SM4. Thus, management module MM1 is linked to switch modules SM1 through SM4 via Ethernet links MM1-ENet1 through MM1-ENet4, and management module MM2 is linked to the switch modules via Ethernet links MM2-ENet1 through MM2-ENet4. In addition, the management modules are also coupled to the switch modules via two well known serial I2C buses SM-I2C-BusA and SM-I2C-BusB, which provide for “out-of-band” communication between the management modules and the switch modules. Similarly, the management modules are also coupled to the power modules PM1 through PM4 via two serial I2C buses PM-I2 C-BusA and PM-I2C-BusB. Two more I2C buses Panel-I2C-BusA and Panel-I2C-BusB are coupled to media tray MT and the rear panel. Blowers BL1 and BL2 are controlled over separate serial buses Fan1 and Fan2. Two well known RS485 serial buses RS485-A and RS485-B are coupled to server blades PB1 through PB14 for “out-of-band” communication between the management modules and the server blades.

FIG. 7 is a topographical illustration of the server blade system's management functions. Referring to FIGS. 3 and 4, each of the two management modules has a 100 Mbps Ethernet port that is intended to be attached to a private, secure management server. The management module firmware supports a web browser interface for either direct or remote access. Each processor blade has a dedicated service processor (SP) for sending and receiving commands to and from the management modules. The data ports that are associated with the switch modules can be used to access the processor blades for image deployment and application management, but are not intended to provide chassis management services. A management and control protocol allows the management module to authenticate individual blades as part of the blade activation procedure. A management module can also send alerts to a remote console to indicate changes in status, such as removal or addition of a blade or module. A management module also provides access to the internal management ports of the switch modules and to other major chassis subsystems (power, cooling, control panel, and media drives).

The management module communicates with each processor blade service processor via the out-of-band serial bus, with one management module acting as the master and the processor blade's service processor acting as a slave. For redundancy, there are two serial busses (one bus per midplane connector) to communicate with each processor blade's service processor. The processor bade is responsible for activating the correct interface to the top or bottom midplane connector based upon the state of the signals from the active management module. When two management modules are installed, the module in slot 1 will normally assume the active management role, while the module in slot 2 will be reserved as a standby module. In event of management module failure or removal after the chassis subsystems have been initialized, the operation of the processor blades and switch subsystems are not affected. Thus, if both management modules are inactive or removed, the server blade system's components will continue to function, but chassis configuration cannot be changed. Addresses are hardwired for each slot on each top and bottom midplane connector, and used by a processor blade's service processor to determine which processor blade is being addressed on the serial bus.

Each of the four switch modules SM1 through SM4 has a dedicated 100 Mbps Ethernet link to the two management modules MM1 and MM2. This provides a secure high-speed communication path to each of the switch modules for control and management purposes only. The I2C serial links are used by the management module to internally provide control of the switch module and to collect system status and vendor product data (“VPD”) information. To accomplish this, the various control and data areas within the switch modules, such as status and diagnostic registers and VPD information, are accessible by the management module firmware. In general, the active management module can detect the presence, quantity, type, and revision level of each blade, power module, blower, and midplane in the system, and can detect invalid or unsupported configurations (e.g., processor blades with Fibre Channel daughter cards connected to Ethernet switch modules.) This function relies upon VPD information within each subsystem as well as signals from the various hardware interfaces or communication via the service processor protocols.

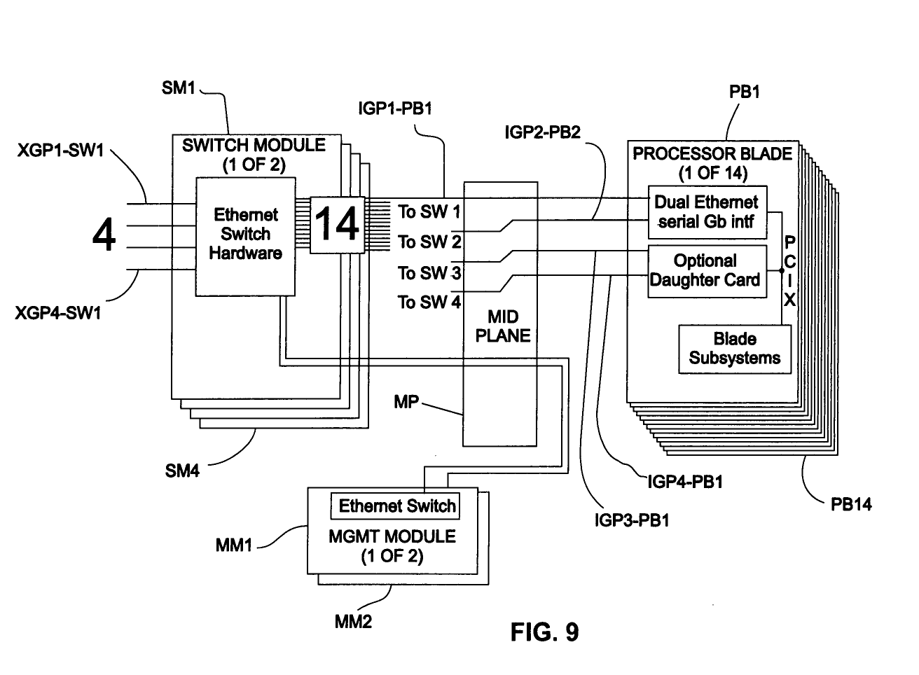

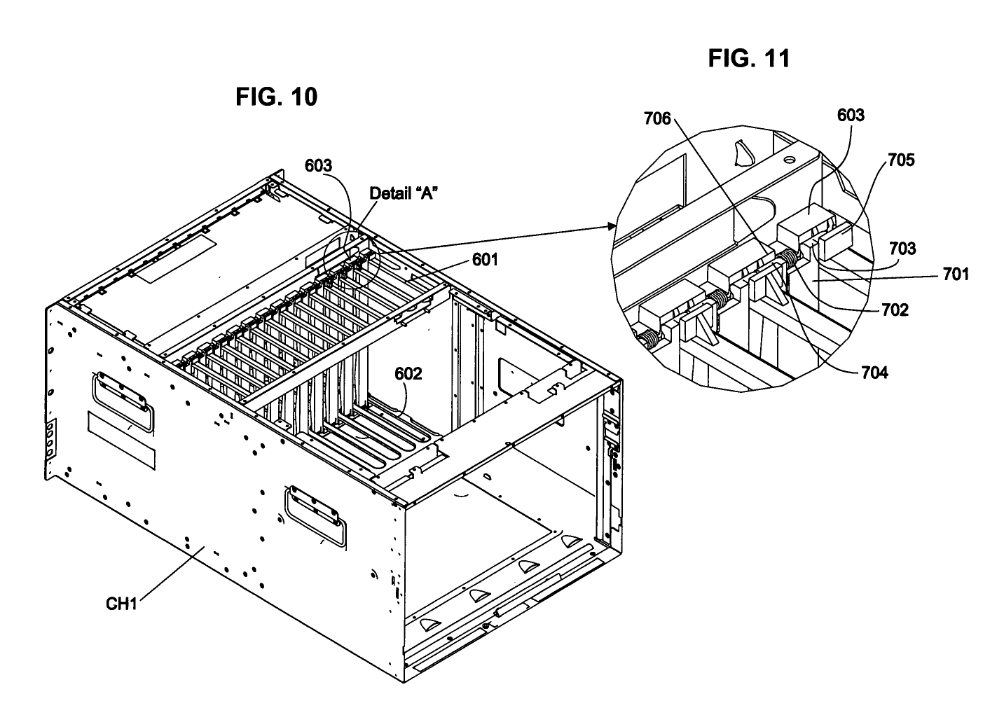

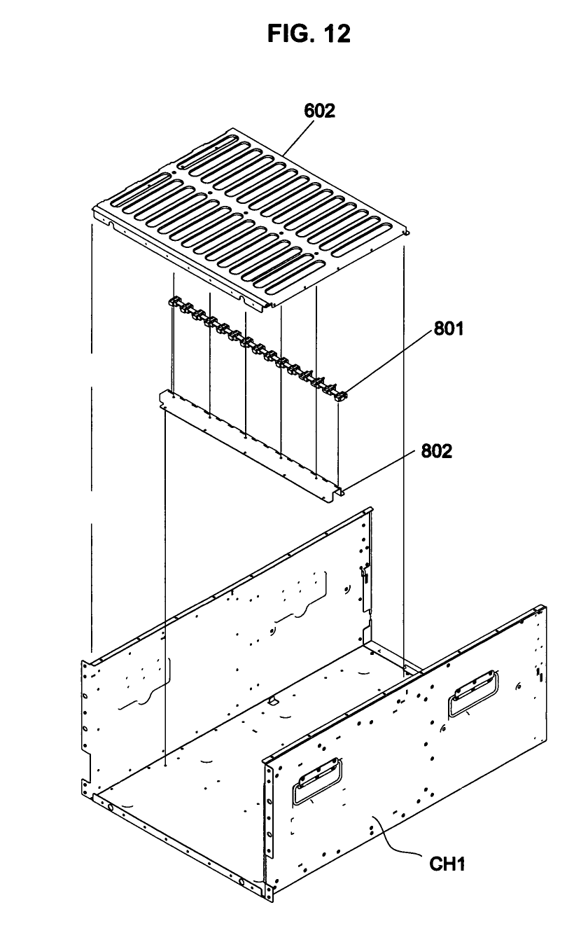

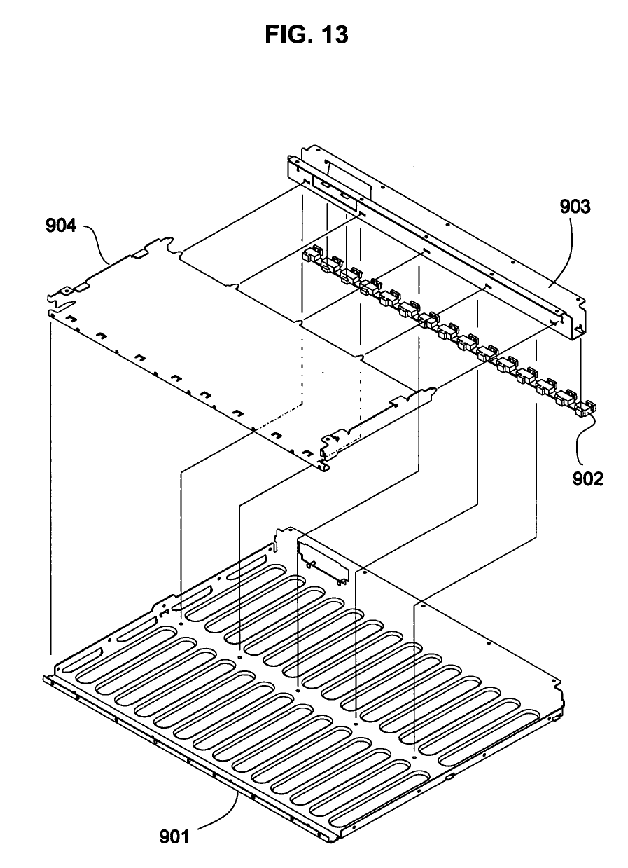

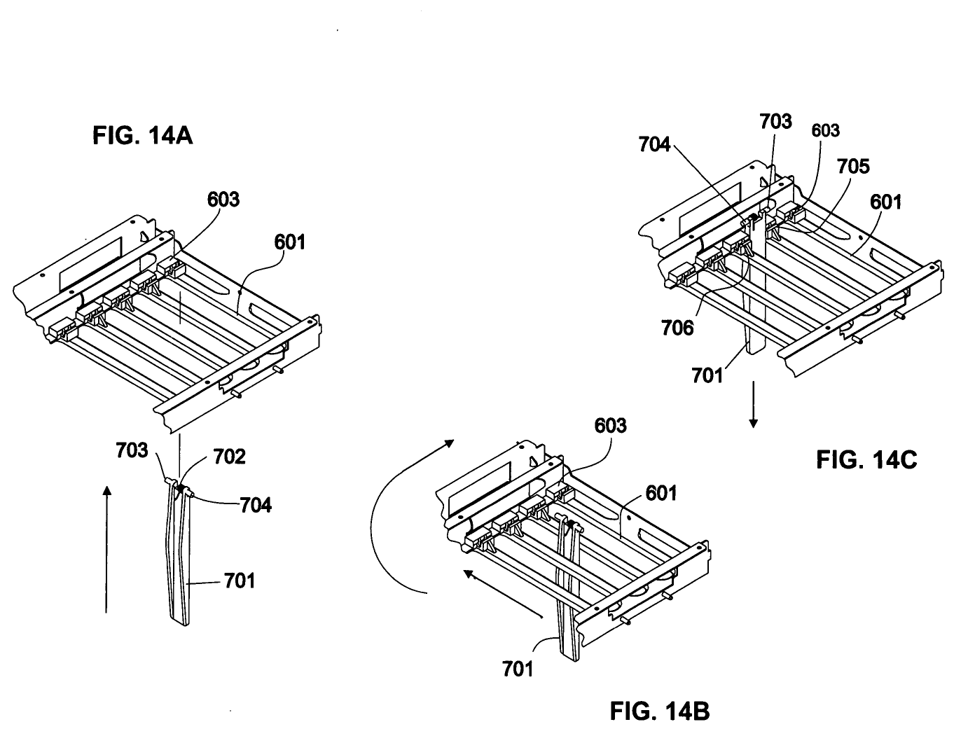

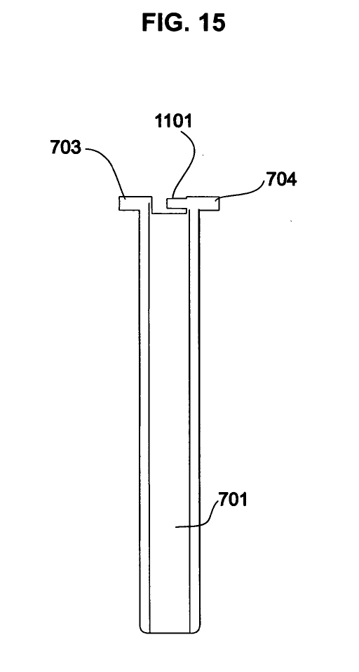

FIG. 9 is a block diagram of the switch module and processor blade interconnection. Referring to this figure, each switch module SW1 through SW4 includes four external gigabit ports. For example, switch module SW1 includes external gigabit ports XGP1-SW1 through XGP4-SW1. Each processor blade includes four internal gigabit ports coupling the processor blade to each one of the four switch modules through the midplane connectors. For example, processor blade PB1 includes four internal gigabit ports IGP1-PB1 through IGP4-PB1. In addition, each management module is coupled to the switch module via an Ethernet link.

The Ethernet Switch Modules are hot-pluggable components that provide Ethernet switching capabilities to the server blade system. The primary purpose of the switch module is to provide Ethernet interconnectivity between the processor blades, management modules and the outside network infrastructure. Depending on the application, the external Ethernet interfaces may be configured to meet a variety of requirements for bandwidth and function. One Ethernet switch module is included in the base system configuration, while a second Ethernet switch module is recommended for redundancy. Each processor blade has a dedicated, 1000 Mbps (1 Gbps) full-duplex SERDES link to each of the two switch modules, and each switch module has four external 1 Gbps (RJ45) ports for connection to the external network infrastructure.

Fibre Channel (FC) is an industry standard networking scheme for sharing remote storage devices among a group of servers. Each processor blade includes a connector to accept a Fibre Channel daughter board containing two Fibre Channel ports of 2 Gb each for connection to dual Fibre Channel switch modules. The routing of the Fibre Channel signals occurs through the midplane to the Fibre Channel switch modules in slots 3 and 4 in the rear of the server blade chassis. Each Fibre Channel switch module is hot-pluggable without disruption of blade or chassis operation. The routing of the two Fibre Channel ports is such that one port from each processor blade is wired to one Fibre Channel switch module, and the other port is wired to the other Fibre Channel switch module to provide redundancy. Each Fibre Channel switch module has 2 external 2 Gb ports for attachment to the external Fibre Channel switch and storage infrastructure. This option allows each of the 14 processor blades to have simultaneous access to a Fibre Channel based storage area network (SAN) as well as the Ethernet based communications network.

In the drawings and specifications there has been set forth a preferred embodiment of the invention and, although specific terms are used, the description thus given uses terminology in a generic and descriptive sense only and not for purposes of limitation.

We claim as our invention:

1-24. (Cancelled).

25. Apparatus comprising:
a printed circuit board having a heat releasing semiconductor package mounted thereon and a heat sink engaging said semiconductor package to transfer heat therefrom;
a power supply configured to supply power to said printed circuit board; and
a chassis which houses said power supply and said circuit board; said heat sink having:
a rectilinear body of heat transferring material having opposing first and second planar surfaces;
a first body of fins affixed to said first planar surface and defining a first array of a plurality of elongate tubular channels directing heat transfer fluid flow; and
a second body of fins affixed to said second planar surface and defining a second array of a plurality of elongate tubular channels directing heat transfer fluid flow.

26. Apparatus according to claim 25 wherein said first body of fins extend over substantially the entire area of said first planar surface;

27. Apparatus according to claim 25 wherein said second body of fins extend over less than the entire area of said second planar surface and define an exposed residual rectangular area for engagement with said semiconductor package.

28. Apparatus according to claim 25 wherein said rectilinear body is a plate of a metal having high thermal conductivity.

29. Apparatus according to claim 25 wherein said rectilinear body is a heat pipe.

30. Apparatus according to claim 25 wherein said second planar surface comprises an area defining a heat receiving zone through which heat is transferred from said semiconductor package.

31. Apparatus according to claim 25 wherein said first and second arrays of tubular channels extend parallel one to the other.

32. Apparatus according to claim 25 wherein said first and second arrays of tubular channels define air flow passages.

33. Apparatus comprising:
a chassis which provides a plurality of slots;
a power module which is housed in said chassis and which provides power to at least two of the slots provided by said chassis;
a printed circuit board configured for removable insertion into a slot provided by said chassis and powered by said power module, the printed circuit board having a heat releasing semiconductor package mounted thereon and a heat sink engaging said semiconductor package to transfer heat therefrom; said heat sink having:
a rectilinear body of heat transferring material having opposing first and second planar surfaces;
a first body of fins affixed to said first planar surface and defining a first array of a plurality of elongate tubular channels directing heat transfer fluid flow; and
a second body of fins affixed to said second planar surface and defining a second array of a plurality of elongate tubular channels directing heat transfer fluid flow.

34. Apparatus according to claim 33 wherein said first body of fins extend over substantially the entire area of said first planar surface;

35. Apparatus according to claim 33 wherein said second body of fins extend over less than the entire area of said second planar surface and define an exposed residual rectangular area for engagement with said semiconductor package.

36. Apparatus according to claim 33 wherein said rectilinear body is a plate of a metal having high thermal conductivity.

37. Apparatus according to claim 33 wherein said rectilinear body is a heat pipe.

38. Apparatus according to claim 33 wherein said second planar surface comprises an area defining a heat receiving zone through which heat is transferred from said semiconductor package.

39. Apparatus according to claim 33 wherein said first and second arrays of tubular channels extend parallel one to the other.

40. Apparatus according to claim 33 wherein said first and second arrays of tubular channels define air flow passages.

41. Apparatus according to claim 33 wherein the printed circuit board is hot-pluggable into the slot.

42. Apparatus comprising:
a printed circuit board having a heat releasing semiconductor package mounted thereon and a heat sink engaging said semiconductor package to transfer heat therefrom;
a power supply configured to supply power to said printed circuit board; and
a chassis which houses said power supply and said circuit board; said heat sink having:
a rectilinear body of heat transferring material having opposing first and second planar surfaces, said planar surfaces extending parallel to said printed circuit board;
a first body of fins affixed to said first planar surface so as to extend away from said printed circuit board and defining a first array of a plurality of elongate tubular channels directing heat transfer fluid flow;
a second body of fins affixed to said second planar surface so as to extend toward said printed circuit board and defining a second array of a plurality of elongate tubular channels directing heat transfer fluid flow.

43. Apparatus comprising:
a chassis which provides a plurality of slots;
a power module which is housed in said chassis and which provides power to at least two of the slots provided by said chassis;
a printed circuit board configured for removable insertion into a slot provided by said chassis and powered by said power module, the printed circuit board having a heat releasing semiconductor package mounted thereon and a heat sink engaging said semiconductor package to transfer heat therefrom; said heat sink having:
a rectilinear body of heat transferring material having opposing first and second planar surfaces, said planar surfaces extending parallel to said printed circuit board;
a first body of fins affixed to said first planar surface so as to extend away from said printed circuit board and defining a first array of a plurality of elongate tubular channels directing heat transfer fluid flow; and
a second body of fins affixed to said second planar surface so as to extend toward said printed circuit board and defining a second array of a plurality of elongate tubular channels directing heat transfer fluid flow.

44. Apparatus according to claim 33 wherein the printed circuit board is hot-pluggable into the slot.

45. Apparatus comprising:
a chassis which provides a plurality of slots;
a power module which is housed in said chassis and which provides power to at least two of the slots provided by said chassis;
a printed circuit board configured for removable insertion into a slot provided by said chassis and powered by said power module, the printed circuit board having a heat releasing semiconductor package mounted thereon and a heat sink engaging said semiconductor package to transfer heat therefrom; said heat sink having:
a plate of heat transferring material having opposing first and second planar surfaces;
a first body of fins affixed to said first planar surface and defining a first array of a plurality of elongate tubular channels directing heat transfer fluid flow parallel to said circuit board ; and
a second body of fins affixed to said second planar surface and defining a second array of a plurality of elongate tubular channels directing heat transfer fluid flow parallel to said circuit board, said second body of fins extending over a only portion of said second planar surface to define a residual area which engages said heat-transfer surface of said semiconductor package for heat transfer.

46. Apparatus according to claim 33 wherein the printed circuit board is hot-pluggable into the slot.
